(19) United States
(12) Patent Application Publication
(10) Pub. No.: US 2002/0025664 A1
(43) Pub. Date: Feb. 28, 2002

(54) Process for production of gate electrode and gate electrode structure

(75) Inventors: Akio Wakejima, Tokyo (JP); Norihiko Samoto, Tokyo (JP); Walter Contrata, Tokyo (JP)

Correspondence Address: Attn: Norman P. Soloway, HAYES, SOLOWAY, HENNESSEY,, GROSSMAN & HAGE, P.C., 175 Canal Street, Manchester, NH, 03101, US

(73) Assignee: NEC Corporation

(21) Appl. No.: 09/938,880

(22) Filed: Aug. 24, 2001

(30) Foreign Application Priority Data
Aug. 25, 2000 (JP) 2000-255780

(51) Int. Cl. H01L 21/338; H01L 21/3205; H01L 21/4763; H01L 21/44; H01L 21/28; H01L 29/76; H01L 31/062

(52) U.S. Cl. 438/585; 438/686; 438/680; 438/665; 438/669; 438/670; 438/574; 438/579; 257/288; 257/412; 257/413

(57) ABSTRACT

There is formed, so as to cover the upper structure (a gold-containing, low-resistance metal layer) of a T- or Y-shaped gate, a thin film (e.g. a thin TiN film) which is not reactive to the low-resistance metal layer, which is resistant to an etching solution to be applied in a later wet etching step, and which has good adhesivity to a resist to be coated in a later step, to prevent the direct contact of the low-resistance metal layer with the resist. In this state, supports are formed.

### BACKGROUND OF THE INVENTION

1. Field of the Invention

The present invention relates to a gate electrode structure in a field effect transistor (FET) using a compound semiconductor, particularly a heterojunction FET-MMIC for millimeter wave band, as well as to a process for production thereof.

2. Description of the Related Art

In FET's using a compound semiconductor such as GaAs, it is well known that reduction in the electrical capacitance between gate and source is requisite in order to achieve high gain at high-frequency. In heterojunction FETs and the like, the gate is a metallic electrode that is in physical contact with semiconductor in a rectangular area. The short side of the rectangle is known as the gate length, and the long side is known as the gate width. The gate capacitance may be reduced by shortening the length or width, but it is preferable to shorten the length, because the width also determines the output power. As the gate length is reduced, the gain increases, but the improvement is limited due to increasing gate resistance. To reduce the gate resistance, gate metals are piled on top of the rectangular contact area, with a “Y-shape” or “T-shape” cross-section. Thus the gate has a top-heavy shape, where it contacts the semiconductor in a narrow rectangle at the bottom, and the cross section widens with increasing height. A gate electrode having such a sectional shape, tends to fall to the side or peel off of the semiconductor, resulting in low production yield.

To prevent the falling and peeling of such a gate electrode, it was proposed in Japanese Patent No. 2,557,432 to form a plurality of supports consisting of an insulating material, at given intervals at the root of the gate electrode.

A process for production of a gate electrode according to a conventional technique is explained below with reference to FIG. 10.

A SiO₂ film 52 is formed as a spacer on an n-type GaAs substrate 51 by deposition. A resist is coated on the whole surface. Then, a window for gate electrode formation of about 0.1 μm in length is made on a predetermined position of the resist by electron beam application or the like. The SiO₂ film 52 is subjected to dry etching using CF₄ gas, to make a window for gate electrode formation in the SiO₂ film 52. Then, the resist on the window for gate electrode formation is selectively removed to widen the window in the resist to 1 μm. Then, in and above the window for gate electrode formation are formed a WSi, TiN, Pt and Au films in this order by sputtering. A resist is coated and patterned to define the top of the gate. Then the Au/Pt build-up is subjected to patterning by ion milling; thereafter, the TiN film and the WSi film are subjected to reactive ion etching to form a gate 53 (FIG. 10(a)).

A resist is coated on the whole surface, and the resist is removed selectively, whereby resists 54 each of about 1 μm in width are left at intervals of several tens of μm along the gate width so as to each cover part of the gate 53 (FIG. 10(b)).

Using the resists 54 as a mask and HF+NH₄F (buffered hydrofluoric acid: BHF) as an etching solution, the SiO₂ film 52 is subjected to wet etching and removed selectively. The remaining portions of the SiO₂ film become supports 55 for prevention of falling and peeling of the gate 53 (FIG. 10(c)).

A problem with this process is that the etchant BHF can infiltrate between the resists 54 and gate 53 (FIG. 11(a)). Then the BHF etches the SiO₂ beneath the resist, giving supports 55 having the shape shown in FIG. 11(b).

When this occurs, the gate can fall or peel, and the production yield is not improved. BHF infiltration occurs for two reasons. First, the adhesion between resist 54 and Au (the main component of the low-resistance metal layer 533) is poor. Second, the process for patterning the gate tends to produce an undercut of the TiN and WSi underneath the Au. To understand the second reason, consider the details of gate fabrication.

Generally in gate electrodes, a film of a high-melting point metal (e.g. tungsten: W) or its silicide (WSi), or the like is formed at the interface between substrate and electrode in order to enable high power operation, and, in order to obtain reduced resistance, a low-resistance metal film is formed thereon. For formation of the low-resistance metal film, Au is mainly used because it is resistant to the etching solution (generally a buffered hydrofluoric acid) for sacrificial SiO₂ film and moreover has high processability. Au is a very stable metal and cannot be patterned by reactive ion etching (RIE) or the like; therefore, it is inevitably patterned by physical means such as the above-mentioned ion milling or the like. In contrast, TiN and WSi are relatively hard materials and take much time (that is, inefficient) when subjected to physical patterning such as ion milling or the like; therefore, they are etched by reactive dry etching such as RIE or the like. Incidentally, this etching is conducted using the low-resistance metal film subjected to patterning, as a mask to reduce the number of total steps. In particular, Au is used as a mask for etching TiN and WSi, and these metals are completely removed except where covered by Au. At the edges of the Au, some unintentional etching occurs, giving the TiN and WSi an undercut profile.

When a resist pattern is formed only on the gate electrode portions below which supports are to be formed, the adhesivity between resist 54 and Au (which is the main component of the low-resistance metal layer 533) is poor and, moreover, there are cases that the etching of the lower layers (TiN 532 and WSi 531) by RIE or the like allows the TiN and WSi to retreat slightly from the Au/Pt film 533 in the width of gate lengthwise direction; thereby, an etching solution infiltrates through the interface between the resist pattern and Au (FIG. 11(a)) and the SiO₂ film beneath the resist pattern is etched partially to give supports 55 having a shape shown in FIG. 11(b); as a result, there were cases that no intended object was unachievable, sidelong falling and peeling of gate electrode occurred, and the yield of gate electrode production was low.

### SUMMARY OF THE INVENTION

Therefore, the objective of the present invention is to improve the adhesivity between Au and resist or use an etching mask in place of an ordinary photoresist, to form supports of desired shape and improve the yield of gate electrode production.

The present inventors made a study in order to achieve the above objective and, as a result, found out the present invention.

The first aspect of the present invention lies in a process for producing a gate electrode, which comprises steps of:

forming a sacrificial insulating film on a substrate and forming, at the position of the sacrificial insulating film where a gate electrode is to be formed, a hole for gate electrode formation reaching to the substrate;

forming thereon a conductor film composed of a high-melting point metal or its compound so as to fill the hole and further forming a gold-containing, low-resistance metal layer via an adhesion layer;

subjecting the low-resistance metal layer to patterning in a predetermined shape and delving part of the adhesion layer;

forming thereon a thin film which is not reactive to the low-resistance metal layer, which is resistant to an etching solution to be applied in a later wet etching step, and which has good adhesivity to a resist to be coated in a later step;

forming a mask on the thin film and subjecting the adhesion layer and the conductor layer composed of a high-melting metal or its compound, to patterning to form a gate electrode upper structure extending in the hole and on the sacrificial insulating film;

coating a resist on the gate electrode upper structure formed on the sacrificial insulating film and then removing the resist to form a resist pattern on the predetermined portions of the lengthwise direction of the gate electrode upper structure; and

subjecting the sacrificial insulating film to wet etching using the resist pattern as a mask to remove the portion of the sacrificial insulating film having no mask thereon and leave the portions of the sacrificial insulating film having the mask thereon so that the left portions can act as supports for the gate electrode upper structure.

The second aspect of the present invention lies in a process for producing a gate electrode, which comprises steps of:

forming a sacrificial insulating film on a substrate and forming, at the position of the sacrificial insulating film where a gate electrode is to be formed, a hole for gate electrode formation reaching to the substrate;

forming thereon a conductor film composed of a high-melting point metal or its compound so as to fill the hole and further forming a gold-containing, low-resistance metal layer via an adhesion layer;

subjecting the low-resistance metal layer to patterning in a predetermined shape;

conducting reactive dry etching using, as a mask, the patterned low-resistance metal layer to convert the adhesion layer and the conductor film to a shape which extends in the hole and on the sacrificial insulating film and which is slightly recessed inside from the side surface of the low-resistance metal layer and thereby form a gate electrode upper structure;

forming, by CVD, so as to cover the gate electrode upper structure formed on the sacrificial insulating film, a thin film which is not reactive to the low-resistance metal layer, which is resistant to an etching solution to be applied in a later wet etching step, and which has good adhesivity to a resist to be coated in a later step, so that the thickness of the thin film becomes at least larger than the thickness of the recessed portions of the adhesion layer and the conductor film;

subjecting the thin film to reactive dry etching to remove the thin film other than one deposited on the recessed sides of the adhesion layer and the conductor film so that the side of the low-resistance metal layer and the left thin film are flush with each other;

coating a resist thereon and then removing the resist to form a resist pattern on the predetermined portions of the lengthwise direction of the gate electrode upper structure; and

subjecting the sacrificial insulating film to wet etching using the resist pattern as a mask to remove the portion of the sacrificial insulating film having no mask thereon and leave the portions of the sacrificial insulating film having the mask thereon so that the left portions can act as supports for the gate electrode upper structure.

The third aspect of the present invention lies in a process for producing a gate electrode, which comprises steps of:

forming a sacrificial insulating film on a substrate and forming, at the position of the sacrificial insulating film where a gate electrode is to be formed, a hole for gate electrode formation reaching to the substrate;

forming thereon a conductor film composed of a high-melting point metal or its compound and an adhesion layer so as to fill the hole;

subjecting the conductor film and the adhesion layer to patterning in a width larger than the width of a gold-containing, low-resistance metal layer to be formed in a later step, to form a gate electrode upper structure extending in the hole and on the sacrificial insulating film;

coating a resist so as to cover the gate electrode upper structure formed on the sacrificial insulating film and then removing the resist to form a resist pattern on the predetermined portions of the lengthwise direction of the gate electrode upper structure;

subjecting the sacrificial insulating film to wet etching using the resist pattern as a mask to remove the portion of the sacrificial insulating film having no mask thereon and leave the portions of the sacrificial insulating film having the mask thereon so that the left portions can act as supports for the gate electrode upper structure; and

forming, on the gate electrode upper structure, a gold-containing, low-resistance metal layer by a deposition and lift-off technique.

The fourth aspect of the present invention lies in a process for producing a gate electrode, which comprises steps of:

forming a sacrificial insulating film on a substrate and forming, at the position of the sacrificial insulating film where a gate electrode is to be formed, a hole for the gate electrode formation reaching to the substrate;

forming thereon a conductor film composed of a high-melting point metal or its compound so as to fill the hole and further forming a gold-containing, low-resistance metal layer via an adhesion layer;

a step of subjecting the low-resistance metal layer, the adhesion layer and the conductor film to patterning to form a gate electrode upper structure extending in the hole and on the sacrificial insulating film;

forming, so as to cover the gate electrode upper structure formed on the sacrificial insulating film, a mask film having such a thickness that the mask film is etched simultaneously with the sacrificial insulating film in a later wet etching step and is removed together with the sacrificial insulating film at the completion of the etching of the sacrificial insulating film, coating a resist on the mask film, and then removing the resist to form a resist pattern at the predetermined portions of the lengthwise direction of the gate electrode upper structure;

subjecting the mask film to patterning using the resist pattern as a mask; and

removing the resist pattern and then subjecting the sacrificial insulating film and the patterned mask film to wet etching to remove the portion of the sacrificial insulating film having no mask film thereon and leave the portions of the sacrificial insulating film below the patterned mask film so that the left portions can act as supports for the gate electrode upper structure.

The present invention further relates to the gate electrode structures produced by the processes of the above first to third aspects. These structures are as follows.

The gate electrode structure corresponding to the first aspect is a gate electrode structure comprising:

a gate electrode of T-shaped or Y-shaped section having a lower portion extending upward vertically from a semiconductor layer and an upper layer extending in the direction of channel length from the lower portion, and

a plurality of supports consisting of an insulating film, present between the upper portion and the semiconductor layer,

wherein the upper portion has a laminated structure consisting of at least a conductor layer composed of a high-melting point metal or its compound, an adhesion layer and a gold-containing, low-resistance metal layer in this order with the conductor layer being at the lowest position, and the whole surface of the low-resistance metal layer is covered with a thin TiN film.

The gate electrode structure corresponding to the second aspect is a gate electrode structure comprising:

a gate electrode of T-shaped or Y-shaped section having a lower portion extending upward vertically from a semiconductor layer and an upper layer extending in the direction of channel length from the lower portion, and

a plurality of supports consisting of an insulating film, present between the upper portion and the semiconductor layer,

wherein the upper portion has a laminated structure consisting of at least a conductor layer composed of a high-melting point metal or its compound, an adhesion layer and a gold-containing, low-resistance metal layer in this order with the conductor layer being at the lowest position; at least the sides of the gate lengthwise direction of each of the conductor layer and the adhesion layer are recessed inwardly from the sides of the low-resistance metal layer; and the whole surface of the recessed sides is covered with a thin TiN film.

The gate electrode structure corresponding to the third aspect is a gate electrode structure comprising:

a gate electrode of T-shaped or Y-shaped section having a lower portion extending upward vertically from a semiconductor layer and an upper layer extending in the direction of channel length from the lower portion, and

a plurality of supports consisting of an insulating film, present between the upper portion and the semiconductor layer,

wherein the upper portion has a laminated structure consisting of at least a conductor layer composed of a high-melting point metal or its compound, an adhesion layer and a gold-containing, low-resistance metal layer in this order with the conductor layer being at the lowest position; the low-resistance metal layer is formed by a lift-off technique after the formation of the supports; and the sides of the gate lengthwise direction of each of the conductor layer and the adhesion layer are protruded outwardly from the sides of the low-resistance metal layer.

According to the present invention, an etching solution does not infiltrate through the interface between resist and gold, or, even if infiltration has occurred, the etching solution does not reach a lower layer which is a sacrificial insulating layer; as a result, supports of desired shape can be formed and reduction in yield due to sidelong falling or peeling of gate electrode can be suppressed.

### BRIEF DESCRIPTION OF THE DRAWINGS

FIG. 1(a) to FIG. 1(c) are sectional views showing production steps up to formation of Y-shaped opening (these steps are common to all aspects of the present invention).

FIG. 2(a) to FIG. 2(d) are sectional views explaining production steps according to the first aspect of the present invention.

FIG. 3 is sectional views explaining the wet etching step conducted after FIG. 2.(a) and (c) each show a portion of gate electrode structure where a resist pattern is formed and supports are to be left or are left; and (b) and (c) each show a portion of gate electrode structure where no resist pattern is formed and the insulating film is to be removed or is removed.

FIG. 4(a) and FIG. 4(b) are sectional views explaining production steps according to the third aspect of the present invention.

FIG. 5 is sectional views explaining the wet etching step conducted after FIG. 4(a) and (c) each show a portion of gate electrode structure where a resist pattern is formed and supports are to be left or are left; and (b) and (c) each show a portion of gate electrode structure where no resist pattern is formed and the insulating film is to be removed or is removed.

FIG. 6 is a sectional view showing the formation of a low-resistance metal layer by a lift-off technique.

FIG. 7(a) and FIG. 7(b) are sectional views explaining production steps according to the second aspect of the present invention.

FIG. 8(a) and FIG. 8(b) are sectional views explaining production steps according to the fourth aspect of the present invention.

FIG. 9 is a sectional view explaining the gate electrode structure obtained by the wet etching conducted after FIG. 8.

FIG. 10(a) to FIG. 10(c) are schematic perspective views explaining the steps for production of gate electrode by a conventional technique.

FIG. 11(a) and FIG. 11(b) are sectional views explaining the problem of a conventional technique.

### DETAILED DESCRIPTION OF THE PREFERRED EMBODIMENTS

In the inventions according to the first and second aspects of the present invention, there is no particular restriction as to “the thin film which is not reactive to the low-resistance metal layer, which is resistant to an etching solution to be applied in a later wet etching step, and which has good adhesivity to a resist to be coated in a later step”. The thin film may be electroconductive or non-electroconductive as long as it satisfies the required conditions. As the thin film, there may be used the same material as used in the adhesion layer. TiN, in particular, is desired because it has good coverability and shows good adhesivity to resist and gold.

As “the mask film” in the invention according to the fourth aspect, any material can be used as long as it is etched simultaneously with the sacrificial insulating film in a later wet etching step and has such a film thickness that can be removed together with the sacrificial insulating film at the completion of the etching of the sacrificial insulating film. In particular, a metal material (e.g. Al) smaller in etching rate than the sacrificial insulating film is preferred because the film thickness of such a material can be small and yet such a material has a reliable mask property.

As the high-melting point metal as the lower layer of the gate electrode, a known material can be used and there can be mentioned tungsten (W), molybdenum (Mo), etc. There can be also used its compound such as a silicide of the high-melting point metal as long as it is electroconductive.

As the adhesion layer, a known material can be used as well. Any material can be used as long as it can improve the adhesivity between (1) the conductor film (a lower layer) composed of a high-melting point metal or its compound and (2) the gold-containing, low-resistance metal layer (an upper layer) and is electroconductive.

In the present invention, the gold-containing, low-resistance metal layer is composed mostly of gold and may contain a Pt layer for prevention of diffusion into lower layer and a Ti layer for adhesivity improvement.

The present invention is described in detail below with reference to the accompanying drawings.

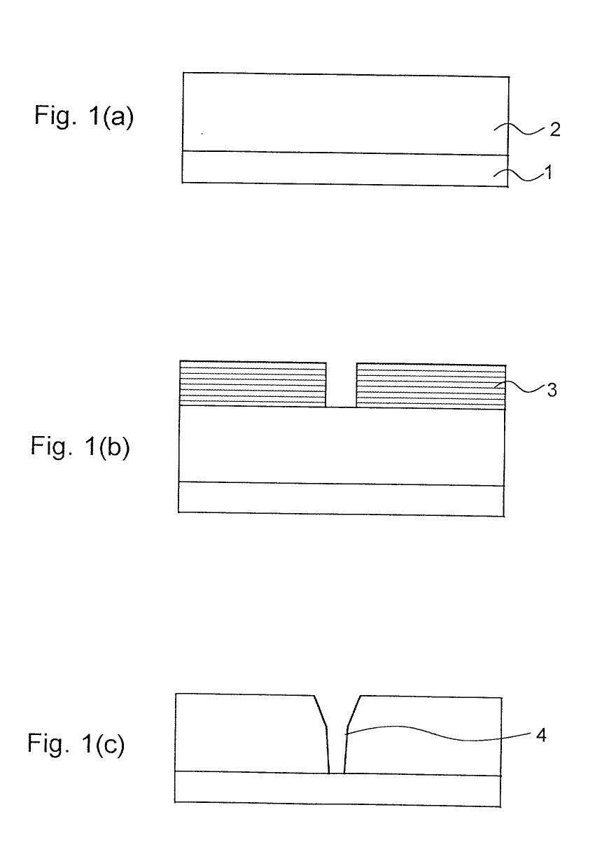

FIGS. 1(a) to 1(c) show steps up to the formation of gate hole in sacrificial SiO₂ film (these steps are common to all the aspects of the present invention). First, on a heterojunction FET epitaxial layer 1 formed on a GaAs substrate (not shown) is formed a SiO₂ film 2 in a thickness of, for example, 300 nm by vacuum CVD (FIG. 1(a)). On the SiO₂ film 2 is coated an electron beam (EB) resist 3. An opening is made in the resist by EB exposure (FIG. 1(b)). Using the EB resist as a mask, reactive dry etching using CF₄ is conducted to make a vertical hole in the SiO₂ film 2. Successively, etching is conducted using SF₆ gas while the resist is being retreated, to make a Y-shaped opening 4 as shown in FIG. 1(c).

Then, description is made on each embodiment.

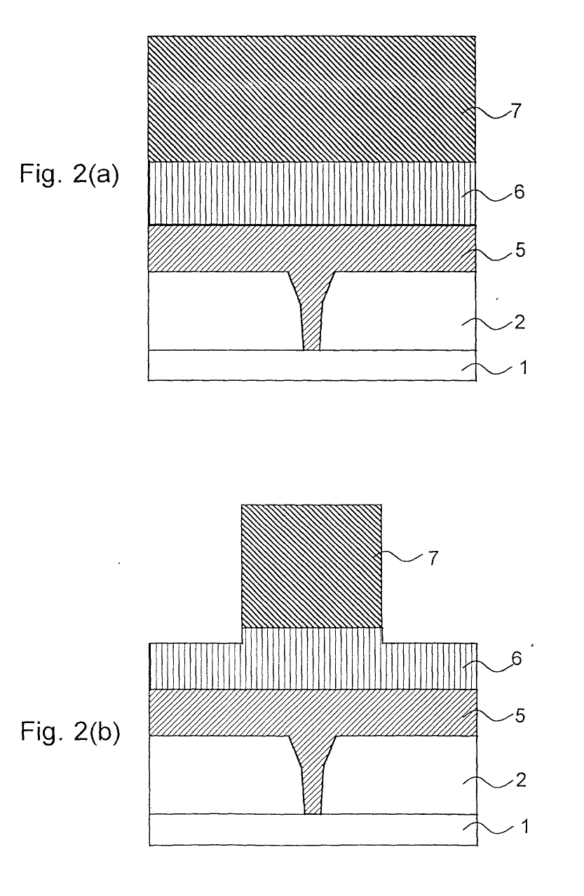

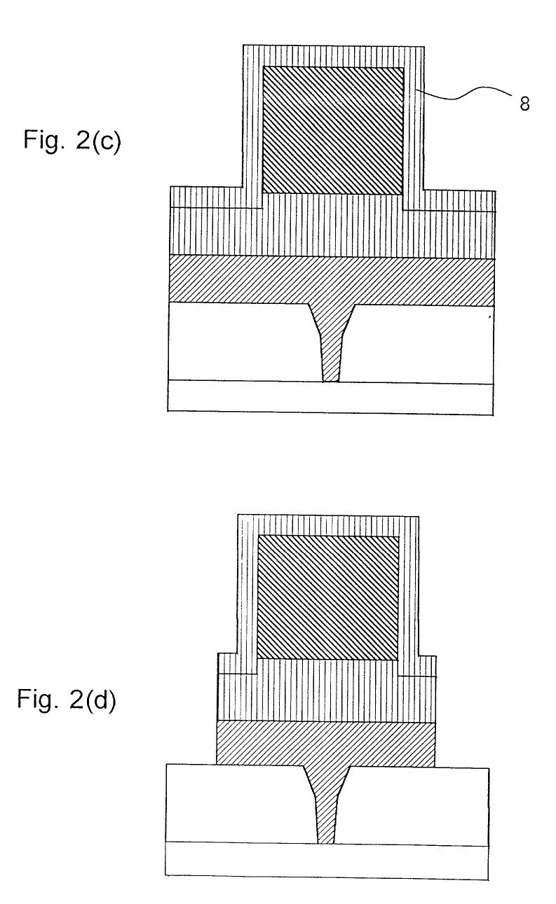

First, the invention according to the first embodiment is described. As shown in FIG. 2(a), there are formed, by sputtering, a conductor film 5 composed of WSi, having a thickness of 150 nm, an adhesion layer 6 composed of TiN, having a thickness of 150 nm and a low-resistance metal layer 7 consisting of a 15-nm Pt film and a 400-nm Au film.

Then, a resist is coated so as to cover the portion of the low-resistance metal layer 7 above the Y-shaped opening 4, and etching is conducted, by Ar ion milling, to etch from Au and Pt down to a certain level of TiN (TiN is left in a thickness of about 100 nm) (FIG. 2(b)).

Successively, on the whole surface is formed, by sputtering, a TiN film 8 in a thickness of about 50 nm (FIG. 2(c)). Then, a resist is coated on the portion of the TiN film 8 above the Y-shaped opening 4, and etching is conducted for the TiN film 8, the adhesion layer 6 and the conductor layer 5 by using, in combination, Ar ion milling and reactive ion etching(RIE), to form a gate electrode shape as shown in FIG. 2(d).

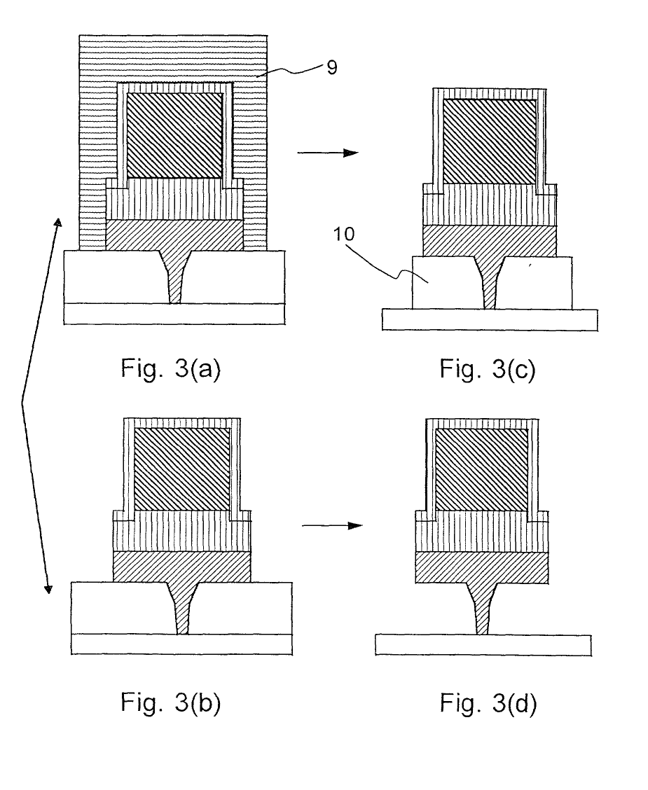

Next, a resist is coated on the whole surface. The coated resist is left as resists 9 on the portions of gate electrode where the SiO₂ film 2 is to be left partially, as shown in FIG. 3(a), and the coated resist is removed at other gate electrode portions, as shown in FIG. 3(b); wet etching is conducted using 16 BHF for 2 minutes, after which the resists 9 are removed; thereby, the SiO₂ film is left as supports 10 beneath the gate electrode portions where the resist has been left, as shown in FIG. 3(c), and the SiO₂ is removed at other gate electrode portions as shown in FIG. 3(d).

In this embodiment, Au (which is poor in adhesivity to resist) is not exposed; therefore, infiltration of BHF through interface (such as mentioned in the prior art) could be prevented and supports of good shape could be obtained.

Next, description is made on the third aspect. In this embodiment, a low-resistance metal layer is formed after the formation of supports.

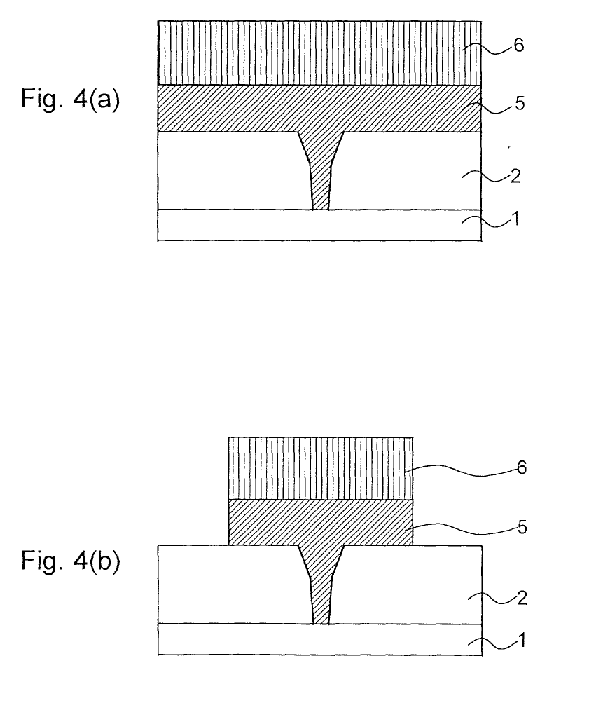

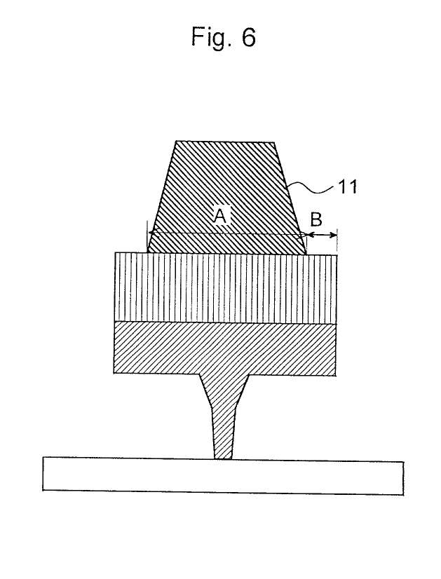

First, on a substrate of FIG. 1(c) are formed, by sputtering, a conductor film 5 composed of WSi, having a thickness of 150 nm and an adhesion layer 6 composed of TiN, having a thickness of 150 nm (FIG. 4(a)). Then, a resist is coated so as to cover the portion of the adhesion layer 6 above the Y-shaped opening 4. The adhesion layer 6 and the conductor film 5 are etched by reactive dry etching, to form a gate electrode lower structure as shown in FIG. 4(b). In this case, the width of the gate length direction of the gate electrode lower structure on the SiO₂ film 2 is made sufficiently large in view of the margin of resist formation because a low-resistance metal layer is formed on the gate electrode lower structure in a later step. In this embodiment, in order to form a low-resistance metal layer 11 of minimum dimension (A=about 0.6 μm) as shown in FIG. 6, the gate electrode lower structure was formed so that the margin B became 0.2 μm at each side and the gate length direction width became about 1 μm.

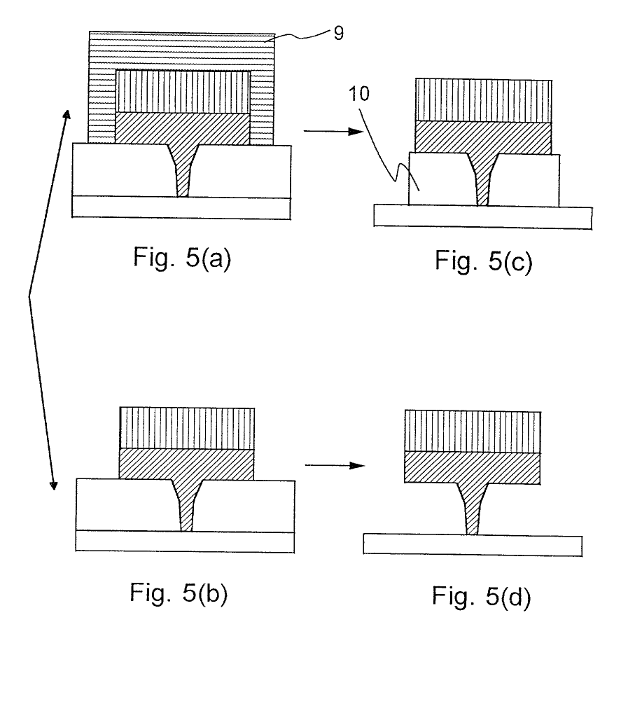

Successively, a resist is coated on the whole surface. The coated resist is left as resists 9 on the portions of gate electrode where the SiO₂ film 2 is to be left partially, as shown in FIG. 5(a), and the coated resist is removed at other gate electrode portions as shown in FIG. 5(b); wet etching is conducted using 16 BHF for 2 minutes, after which the resists 9 are removed; thereby, the SiO₂ film is left as supports 10 beneath the gate electrode portions where the resist has been left, as shown in FIG. 5(c), and the SiO₂ film is removed at other gate electrode portions as shown in FIG. 5(d). Thus, by forming a pattern for supports before the formation of an Au-containing, low-resistance metal layer, infiltration of BHF through interface (such as mentioned in the prior art) could be prevented and supports of good shape could be obtained.

Thereafter, on the above-formed gate electrode lower structure having supports was formed, by a deposition and lift-off technique, a low-resistance metal (Ti/Pt/Au) layer consisting of 25-nm Ti, 25-nm Pt and 400-nm Au, and a gate electrode shown in FIG. 6 was obtained.

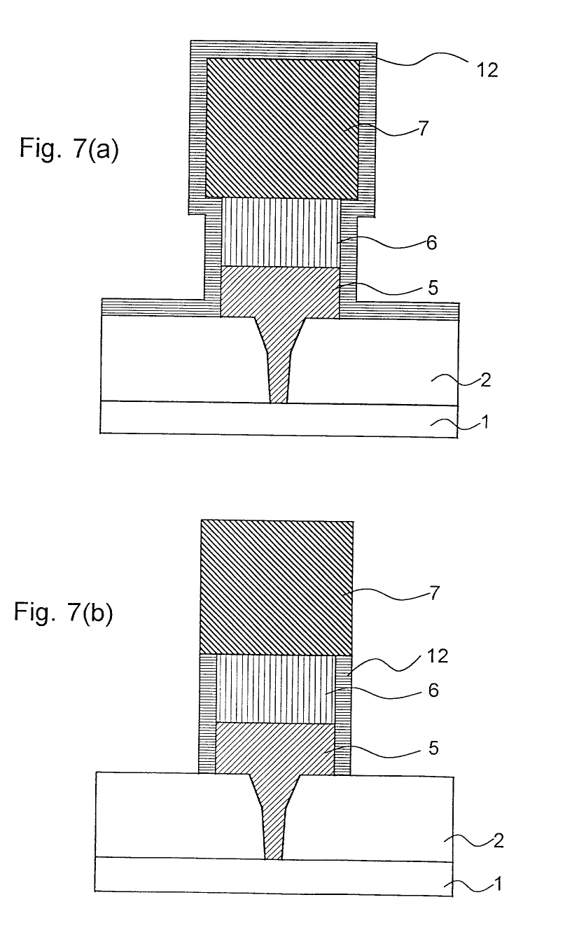

Next, description is made on the second aspect of the present invention. Operation up to formation of a low-resistance metal layer 7 is conducted in the same manners as in FIG. 1 and FIG. 2. Then, TiN and WSi are etched by reactive dry etching in the same manner as in a conventional technique, to form a gate electrode. In this case, as mentioned previously, the TiN film and the WSi film are etched in a shape slightly (about 25 nm) retreated from the upper low-resistance metal layer 7. Successively, a TiN film 12 is formed in a thickness of, for example, 50 nm by metal CVD. In this case, the TiN film 12 is formed uniformly even on the retreated portions (FIG. 7(a)). Then, the TiN film 12 is etched by reactive dry etching, whereby the TiN film 12 remains on the recessed sides of the adhesion layer 6 and the conductor film 6 as shown in FIG. 7(b). Incidentally, the TiN film 12 surrounding the low-resistance metal layer 7 need not be completely removed and may remain as a thin layer. Thus, the sides of the low-resistance metal layer 7 and the sides of the lower adhesion layer 6 and conductor film 6 are made flush with each other. Thereby, even if, in later resist coating and etching, an etching solution infiltrates into the interface between the adhesion layer 6 and the low-resistance metal layer 7, the infiltration is suppressed because the adhesivity between the resist and the TiN film 12 remaining on the sides of the adhesion layer 6 and the conductor film 5 is good; abnormal etching of the SiO₂ film beneath the resist pattern can be prevented; and supports of good shape can be formed.

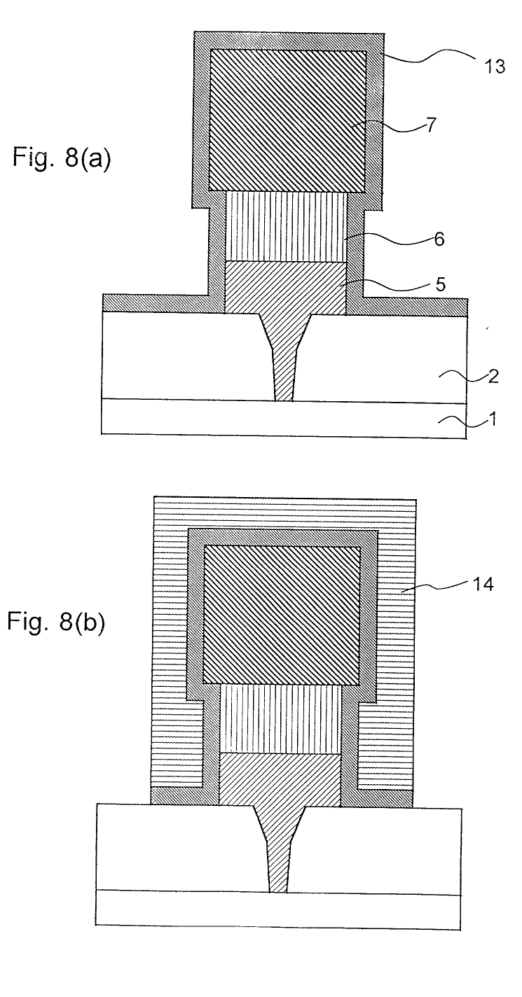

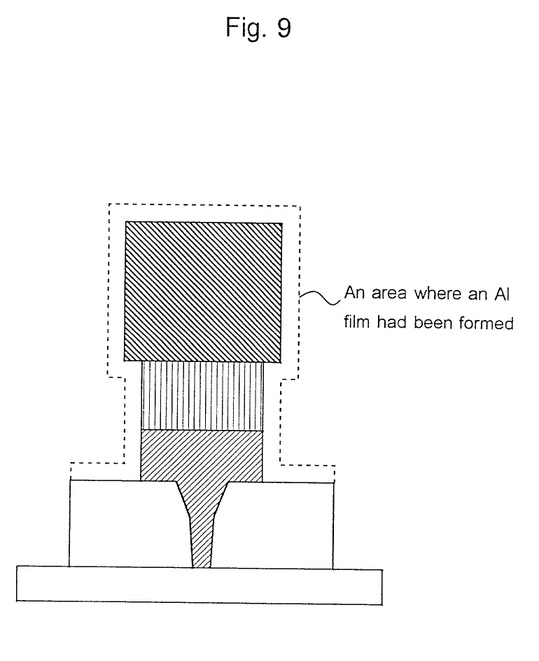

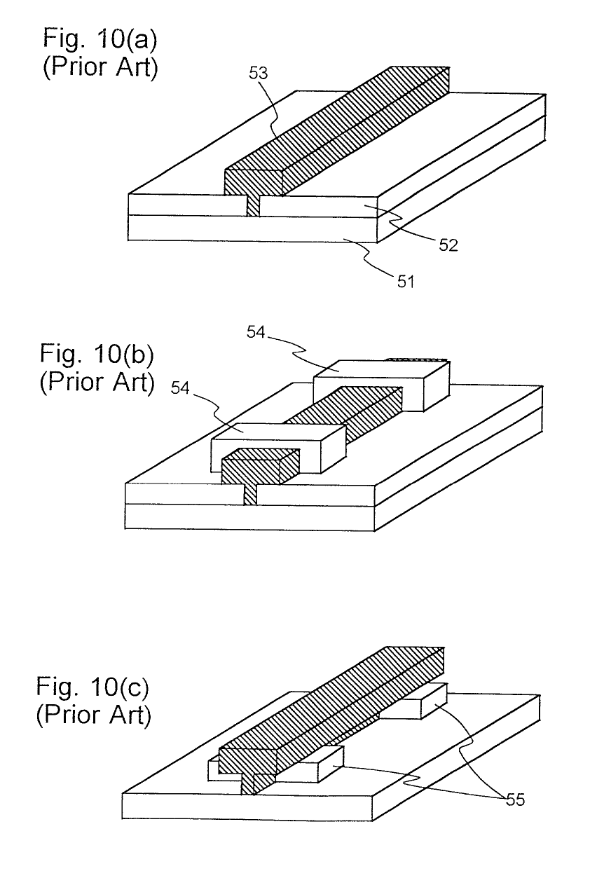

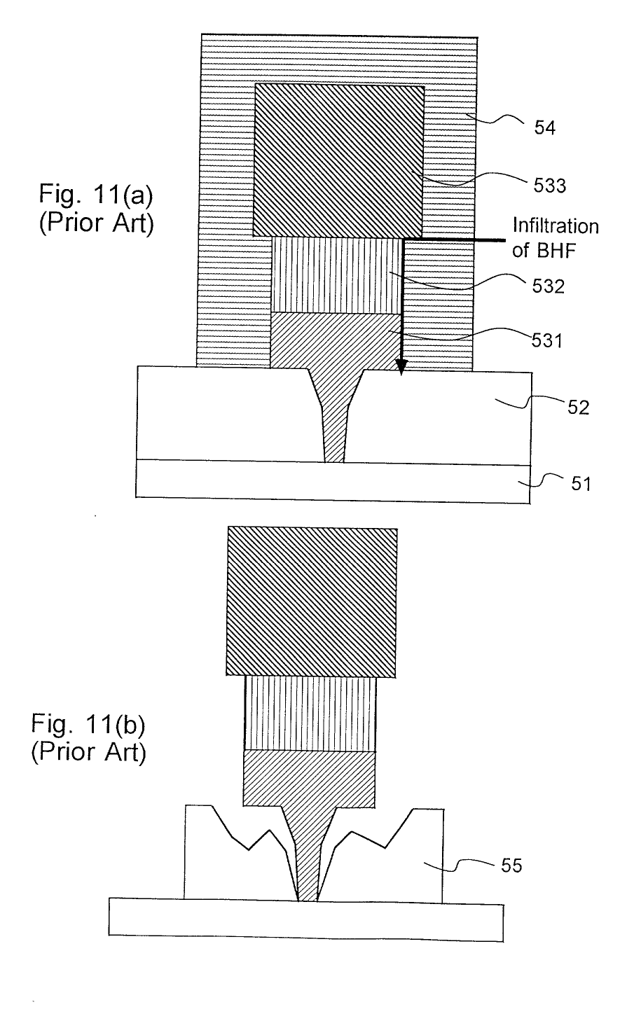

In the above embodiments, a resist was used as a mask for SiO₂ film etching, as done conventionally. In contrast, the fourth aspect of the present invention is characterized by using, as such a mask, a material (e.g. Al) which can be etched by the same etching solution as for Sio₂ and which has good adhesivity to Au. An example of the fourth aspect is described below with reference to FIG. 8 and FIG. 9.

A gate electrode structure is obtained in the same manner as in the second embodiment. Then, on the whole surface is formed an Al film 13 in a thickness of about 50 nm, by vapor deposition. Successively, a resist is coated on the whole surface and a resist pattern is left on the portions of the gate electrode structure where the SiO₂ film is to be left. The Al film 13 is etched by hot phosphoric acid using the resist pattern as a mask. The resist pattern is removed, after which the SiO₂ film is subjected to wet etching by 16 BHF. The Al film is etched simultaneously. However, the etching of the SiO₂ film is delayed at the SiO₂ portions on which the Al film remains; as a result, the SiO₂ film remains at the gate electrode portion on which the Al pattern was formed, as shown in FIG. 9 and functions as supports.

What is claimed is:

1. A process for producing a gate electrode, which comprises steps of:
forming a sacrificial insulating film on a substrate and forming, at the position of the sacrificial insulating film where a gate electrode is to be formed, a hole for gate electrode formation reaching to the substrate;
forming thereon a conductor film composed of a high-melting point metal or its compound so as to fill the hole and further forming a gold-containing, low-resistance metal layer via an adhesion layer;
subjecting the low-resistance metal layer to patterning in a predetermined shape and delving part of the adhesion layer;
forming thereon a thin film which is not reactive to the low-resistance metal layer, which is resistant to an etching solution to be applied in a later wet etching step, and which has good adhesivity to a resist to be coated in a later step;
forming a mask on the thin film and subjecting the adhesion layer and the conductor layer composed of a high-melting metal or its compound, to patterning to form a gate electrode upper structure extending in the hole and on the sacrificial insulating film;
coating a resist on the gate electrode upper structure formed on the sacrificial insulating film and then removing the resist to form a resist pattern on the predetermined portions of the lengthwise direction of the gate electrode upper structure; and
subjecting the sacrificial insulating film to wet etching using the resist pattern as a mask to remove the portion of the sacrificial insulating film having no mask thereon and leave the portions of the sacrificial insulating film having the mask thereon so that the left portions can act as supports for the gate electrode upper structure.

2. A process for producing a gate electrode according to claim 1, wherein the thin film which is not reactive to the low-resistance metal layer, which is resistant to an etching solution to be applied in a later wet etching step, and which has good adhesivity to a resist to be coated in a later step, is a TiN film.

3. A process for producing a gate electrode, which comprises steps of:
forming a sacrificial insulating film on a substrate and forming, at the position of the sacrificial insulating film where a gate electrode is to be formed, a hole for gate electrode formation reaching to the substrate;
forming thereon a conductor film composed of a high-melting point metal or its compound so as to fill the hole and further forming a gold-containing, low-resistance metal layer via an adhesion layer;
subjecting the low-resistance metal layer to patterning in a predetermined shape;
conducting reactive dry etching using, as a mask, the patterned low-resistance metal layer to convert the adhesion layer and the conductor film to a shape which extends in the hole and on the sacrificial insulating film and which is slightly recessed inside from the side surface of the low-resistance metal layer and thereby form a gate electrode upper structure;
forming, by CVD, so as to cover the gate electrode upper structure formed on the sacrificial insulating film, a thin film which is not reactive to the low-resistance metal layer, which is resistant to an etching solution to be applied in a later wet etching step, and which has good adhesivity to a resist to be coated in a later step, so that the thickness of the thin film becomes at least larger than the thickness of the recessed portions of the adhesion layer and the conductor film;
subjecting the thin film to reactive dry etching to remove the thin film other than one deposited on the recessed sides of the adhesion layer and the conductor film so that the side of the low-resistance metal layer and the left thin film are flush with each other;
coating a resist thereon and then removing the resist to form a resist pattern on the predetermined portions of the lengthwise direction of the gate electrode upper structure; and
subjecting the sacrificial insulating film to wet etching using the resist pattern as a mask to remove the portion of the sacrificial insulating film having no mask thereon and leave the portions of the sacrificial insulating film having the mask thereon so that the left portions can act as supports for the gate electrode upper structure.

4. A process for producing a gate electrode according to claim 3, wherein the thin film which is not reactive to the low-resistance metal layer, which is resistant to an etching solution to be applied in a later wet etching step, and which has good adhesivity to a resist to be coated in a later step, is a TiN film.

5. A process for producing a gate electrode, which comprises steps of:
forming a sacrificial insulating film on a substrate and forming, at the position of the sacrificial insulating film where a gate electrode is to be formed, a hole for gate electrode formation reaching to the substrate;
forming thereon a conductor film composed of a high-melting point metal or its compound and an adhesion layer so as to fill the hole;
subjecting the conductor film and the adhesion layer to patterning in a width larger than the width of a gold-containing, low-resistance metal layer to be formed in a later step, to form a gate electrode upper structure extending in the hole and on the sacrificial insulating film;
coating a resist so as to cover the gate electrode upper structure formed on the sacrificial insulating film and then removing the resist to form a resist pattern on the predetermined portions of the lengthwise direction of the gate electrode upper structure;
subjecting the sacrificial insulating film to wet etching using the resist pattern as a mask to remove the portion of the sacrificial insulating film having no mask thereon and leave the portions of the sacrificial insulating film having the mask thereon so that the left portions can act as supports for the gate electrode upper structure; and
forming, on the gate electrode upper structure, a gold-containing, low-resistance metal layer by a deposition and lift-off technique.

6. A process for producing a gate electrode, which comprises steps of:
forming a sacrificial insulating film on a substrate and forming, at the position of the sacrificial insulating film where a gate electrode is to be formed, a hole for the gate electrode formation reaching to the substrate;
forming thereon a conductor film composed of a high-melting point metal or its compound so as to fill the hole and further forming a gold-containing, low-resistance metal layer via an adhesion layer;
a step of subjecting the low-resistance metal layer, the adhesion layer and the conductor film to patterning to form a gate electrode upper structure extending in the hole and on the sacrificial insulating film;
forming, so as to cover the gate electrode upper structure formed on the sacrificial insulating film, a mask film having such a thickness that the mask film is etched simultaneously with the sacrificial insulating film in a later wet etching step and is removed together with the sacrificial insulating film at the completion of the etching of the sacrificial insulating film, coating a resist on the mask film, and then removing the resist to form a resist pattern at the predetermined portions of the lengthwise direction of the gate electrode upper structure;
subjecting the mask film to patterning using the resist pattern as a mask; and
removing the resist pattern and then subjecting the sacrificial insulating film and the patterned mask film to wet etching to remove the portion of the sacrificial insulating film having no mask film thereon and leave the portions of the sacrificial insulating film below the patterned mask film so that the left portions can act as supports for the gate electrode upper structure.

7. A process for producing a gate electrode according to claim 6, wherein the mask film is an aluminum film.

8. A gate electrode structure comprising:
a gate electrode of T-shaped or Y-shaped section having a lower portion extending upward vertically from a semiconductor layer and an upper layer extending in the direction of channel length from the lower portion, and
a plurality of supports consisting of an insulating film, present between the upper portion and the semiconductor layer,
wherein the upper portion has a laminated structure consisting of at least a conductor layer composed of a high-melting point metal or its compound, an adhesion layer and a gold-containing, low-resistance metal layer in this order with the conductor layer being at the lowest position, and the whole surface of the low-resistance metal layer is covered with a thin TiN film.

9. A gate electrode structure comprising:
a gate electrode of T-shaped or Y-shaped section having a lower portion extending upward vertically from a semiconductor layer and an upper layer extending in the direction of channel length from the lower portion, and
a plurality of supports consisting of an insulating film, present between the upper portion and the semiconductor layer,
wherein the upper portion has a laminated structure consisting of at least a conductor layer composed of a high-melting point metal or its compound, an adhesion layer and a gold-containing, low-resistance metal layer in this order with the conductor layer being at the lowest position; at least the sides of the gate lengthwise direction of each of the conductor layer and the adhesion layer are recessed inwardly from the sides of the low-resistance metal layer; and the whole surface of the recessed sides is covered with a thin TiN film.

10. A gate electrode structure comprising:
a gate electrode of T-shaped or Y-shaped section having a lower portion extending upward vertically from a semiconductor layer and an upper layer extending in the direction of channel length from the lower portion, and
a plurality of supports consisting of an insulating film, present between the upper portion and the semiconductor layer,
wherein the upper portion has a laminated structure consisting of at least a conductor layer composed of a high-melting point metal or its compound, an adhesion layer and a gold-containing, low-resistance metal layer in this order with the conductor layer being at the lowest position; the low-resistance metal layer is formed by a lift-off technique after the formation of the supports; and the sides of the gate lengthwise direction of each of the conductor layer and the adhesion layer are protruded outwardly from the sides of the low-resistance metal layer.
